(19) United States
(12) Patent Application Publication
(10) Pub. No.: US 2024/0291445 A1
(43) Pub. Date: Aug. 29, 2024

(54) MATCHING CIRCUIT

(71) Applicant: Murata Manufacturing Co., Ltd., Kyoto (JP)

(72) Inventor: Yuri HONDA, Kyoto (JP)

(21) Appl. No.: 18/581,770

(22) Filed: Feb. 20, 2024

(30) Foreign Application Priority Data
Feb. 27, 2023 (JP) 2023-028396

(51) Int. Cl. H03F 1/56; H03F 3/21

(52) U.S. Cl. CPC H03F 1/565; H03F 3/21; H03F 2200/387

(57) ABSTRACT

A first resonant circuit and a second resonant circuit are included, the first resonant circuit includes a first inductance element and a first capacitor, the second resonant circuit includes a second inductance element and a second capacitor, one end portion of the first inductance element is connected to an output terminal of an amplifier, another end portion of the first inductance element is connected to one end portion of the second inductance element and one end portion of the first capacitor, and another end portion of the second inductance element is connected to the power source and one end portion of the second capacitor.

### CROSS REFERENCE TO RELATED APPLICATION

This application claims priority from Japanese Patent Application No. 2023-028396 filed on Feb. 27, 2023. The content of this application is incorporated herein by reference in its entirety.

### BACKGROUND OF THE DISCLOSURE

### 1. Field of the Disclosure

The present disclosure relates to matching circuits.

### 2. Description of the Related Art

In some cases, a matching circuit is provided on the output side of a power amplifying circuit (for example, International Publication No. 2008/093477 (Patent Document 1)). In the power amplifying circuit of the patent document 1, a TLT (Transmission Line Transformer) is used as the matching circuit. In the power amplifying circuit of the patent document 1, two TLTs are used.

### BRIEF SUMMARY OF THE DISCLOSURE

By using a two-stage configuration TLT in which two TLTs are used, the power amplifying circuit has the benefit of being able to cut signals outside of a frequency band of a signal to be amplified in this power amplifying circuit. However, there is a drawback of not being able to obtain a sufficient cutoff characteristic in the case where the frequency band that needs to be amplified and frequencies that need to be cut are not sufficiently separated.

The present disclosure is made in view of the above, and a possible benefit thereof is to provide a matching circuit that provides a sufficient cutoff characteristic even in the case where a frequency band of a signal that needs to be amplified and frequencies that need to be cut are not sufficiently separated.

To resolve the issues described above and achieve the possible benefit, a matching circuit according to one aspect of the present disclosure is a matching circuit that is provided on an output side of an amplifier and provides impedance matching, the matching circuit including a first matching circuit, wherein the first matching circuit includes a first resonant circuit connected to an output terminal of the amplifier and a second resonant circuit connected between the first resonant circuit and a power source, the first resonant circuit includes a first inductance element and a first capacitor, the second resonant circuit includes a second inductance element and a second capacitor, one end portion of the first inductance element is connected to the output terminal of the amplifier, another end portion of the first inductance element is connected to one end portion of the second inductance element and one end portion of the first capacitor, another end portion of the second inductance element is connected to the power source and one end portion of the second capacitor, another end portion of the first capacitor is connected to a reference potential, another end portion of the second capacitor is connected to the reference potential, the first matching circuit further includes a third inductance element connected to the output terminal of the amplifier and a fourth inductance element connected to an output side of the third inductance element, the second inductance element and the third inductance element are electromagnetically coupled with one another, and the first inductance element and the fourth inductance element are electromagnetically coupled with one another.

The matching circuit according to the present disclosure can provide a sufficient cutoff characteristic even in the case where a frequency band of a signal that needs to be amplified and frequencies that need to be cut are not sufficiently separated.

### BRIEF DESCRIPTION OF THE SEVERAL VIEWS OF THE DRAWINGS

FIG. 1 is a diagram illustrating a power amplifying circuit including a matching circuit according to a comparative example;

FIG. 2 is a diagram illustrating a configuration of a matching circuit according to a first embodiment of the present disclosure;

FIG. 3 is a diagram illustrating an exemplary configuration of a second matching circuit in FIG. 2;

FIG. 4 is a Smith chart illustrating change of input reflection coefficient with respect to change of frequency of an input signal in the matching circuit according to the first embodiment;

FIG. 5 is a diagram illustrating change of output transmission coefficient with respect to the frequency of an input signal;

FIG. 6 is a diagram illustrating change of the input reflection coefficient with respect to the frequency of an input signal;

FIG. 7 is a diagram illustrating passing loss with respect to change of frequency;

FIG. 8 is a Smith chart illustrating change of the input reflection coefficient with respect to change of the frequency of an input signal;

FIG. 9 is a diagram illustrating change of the output transmission coefficient with respect to the change of the frequency of an input signal;

FIG. 10 is a diagram illustrating a configuration of a matching circuit according to a second embodiment of the present disclosure;

FIG. 11 is a diagram illustrating a configuration of a matching circuit according to a third embodiment of the present disclosure;

FIG. 12 is a Smith chart illustrating change of input reflection coefficient with respect to change of frequency of an input signal in the matching circuit according to the third embodiment;

FIG. 13 is a diagram illustrating change of output transmission coefficient with respect to the frequency of an input signal;

FIG. 14 is a diagram illustrating a configuration of a matching circuit according to a fourth embodiment of the present disclosure;

FIG. 15 is a diagram illustrating a configuration of a matching circuit according to a fifth embodiment of the present disclosure; and

FIG. 16 is a diagram illustrating a configuration of a matching circuit according to a sixth embodiment of the present disclosure.

### DETAILED DESCRIPTION OF THE DISCLOSURE

Hereinafter, embodiments of the present disclosure will be described in detail with reference to the drawings. In the description of each of the following embodiments, constituent elements identical or equivalent to those of another embodiment are denoted by the same reference characters, and descriptions thereof are simplified or omitted. The present disclosure is not limited by each embodiment. Further, constituent elements of the respective embodiments include ones that are easy and can be replaced by a person skilled in the art or substantially identical ones. Note that the constituent elements described below can be combined if appropriate. Further, constituent elements can be omitted, replaced, or modified as long as they do not depart from the scope of the present disclosure.

First, to facilitate understanding of embodiments, a comparative example is described.

### COMPARATIVE EXAMPLE

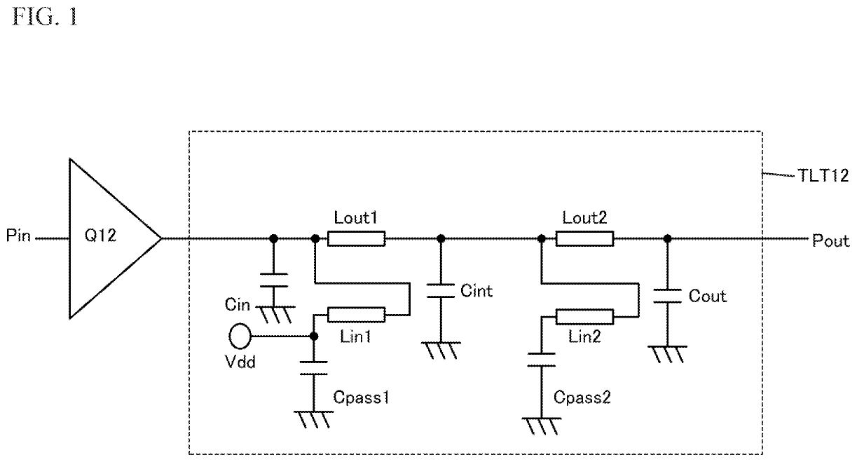

FIG. 1 is a diagram illustrating a power amplifying circuit including a matching circuit according to a comparative example. The power amplifying circuit illustrated in FIG. 1 uses a matching circuit including a TLT (Transmission Line Transformer). In FIG. 1, a transmission line transformer TLT12 is provided on the output side of an amplifying element Q12. The transmission line transformer TLT12 has the capability of matching circuit.

In FIG. 1, the amplifying element Q12 amplifies an input signal inputted to an input terminal Pin. The transmission line transformer TLT12 is connected to the output side of the amplifying element Q12.

The transmission line transformer TLT12 includes a line Lout1, a line Lout2, a line Lin1, a line Lin2, a capacitor Cin, a capacitor Cint, a capacitor Cout, a capacitor Cpass1, a capacitor Cpass2, and a power source Vdd.

One end portion of the line Lout1 is connected to the output side of the amplifying element Q12. The other end portion of the line Lout1 is connected to one end portion of the line Lout2. The line Lout2 is connected to the line Lout1 in series. The other end portion of the line Lout2 is connected to an output terminal Pout.

One end portion of the line Lin1 is connected to one end portion of the line Lout1. The other end portion of the line Lin1 is connected to a reference potential via the capacitor Cpass1. The line Lout1 and the line Lin1 are electromagnetically coupled with each other. The line Lout1 and the line Lin1 function as a TLT.

One end portion of the line Lin2 is connected to one end portion of the line Lout2. The other end portion of the line Lin2 is connected to the reference potential via the capacitor Cpass2. The line Lout2 and the line Lin2 are electromagnetically coupled with each other. The line Lout2 and the line Lin2 function as a TLT.

One end portion of the capacitor Cin is connected to one end portion of the line Lout1. The other end portion of the capacitor Cin is connected to the reference potential. One end portion of the capacitor Cint is connected to the other end portion of the line Lout1 and one end portion of the line Lout2. The other end portion of the capacitor Cint is connected to the reference potential. One end portion of the capacitor Cout is connected to the other end portion of the line Lout2. The other end portion of the capacitor Cout is connected to the reference potential.

The comparative example described above uses a two-stage TLT that includes the TLT made up of the line Lout1 and the line Lin1 and the TLT made up of the line Lout2 and the line Lin2. Compared to the case where a single-stage TLT is used, the use of a two-stage TLT has the benefit of being able to cut signals outside of a first frequency band of a signal to be amplified by the amplifying element Q12. However, there is a drawback of not being able to obtain a sufficient cutoff characteristic in the case where the first frequency band that needs to be amplified and frequencies that need to be cut are not sufficiently separated. For example, in the case where the frequency of a signal to be amplified by the amplifying element Q12 is 1.9 GHz and the frequency of an out-of-band signal is 2.4 GHz, it is difficult to obtain a sufficient cutoff characteristic.

### EMBODIMENTS

Next, embodiments are described.

### First Embodiment

### Configuration

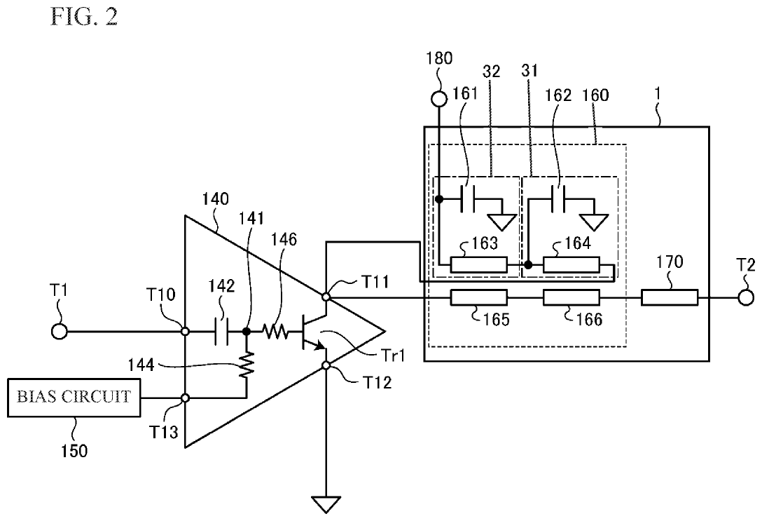

FIG. 2 is a diagram illustrating a configuration of a matching circuit according to the first embodiment of the present disclosure. In FIG. 2, a matching circuit 1 according to the first embodiment of the present disclosure includes a matching circuit 160 that is a first matching circuit and a matching circuit 170 that is a second matching circuit. The matching circuit 160 is provided on the output side of an amplifier 140 and provides impedance matching. The matching circuit 160 includes capacitors 161 and 162 and lines 163, 164, 165, and 166. The other end portion of the matching circuit 160 is connected to a power source 180.

The lines 163, 164, 165, and 166 are all inductance elements realized by wiring patterns. The inductance element is an element that has an inductance value.

One end portion of the line 164 that is a first inductance element is connected to an output terminal T11 of the amplifier 140. The other end portion of the line 164 is connected to one end portion of the line 163 that is a second inductance element. The other end portion of the line 163 is connected to the power source 180. One end portion of the line 165 that is a third inductance element is connected to the output terminal T11 of the amplifier 140. The other end portion of the line 165 is connected to one end portion of the line 166 that is a fourth inductance element. The other end portion of the line 166 is connected to one end portion of the matching circuit 170 that is the second matching circuit. The other end portion of the matching circuit 170 is connected to an output terminal T2.

The line 163 and the line 165 are electromagnetically coupled with each other. The line 164 and the line 166 are electromagnetically coupled with each other. Note that in FIG. 2, the line 165 and the line 166 are illustrated as different wiring lines. However, the line 165 and the line 166 may alternatively be realized by the same wiring line.

One end portion of the capacitor 161 is connected to the other end portion of the line 163 and the power source 180. The other end portion of the capacitor 161 is connected to a reference potential. One end portion of the capacitor 162 is connected to an connection point between the other end portion of the line 164 and one end portion of the line 163. The other end portion of the capacitor 162 is connected to the reference potential. Note that the reference potential is, for example, a ground potential. The same applies to the description below.

Each of the lines 163, 164, 165, and 166 can be realized by a wiring pattern or wiring patterns on a substrate. The same applies to the description below.

### Second Matching Circuit

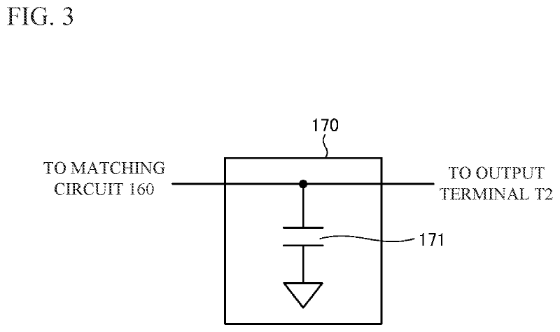

FIG. 3 is a diagram illustrating an exemplary configuration of the matching circuit 170 that is the second matching circuit in FIG. 2. The matching circuit 170 illustrated in FIG. 3 includes a capacitor 171. One end portion of the capacitor 171 is connected between the matching circuit 160 and the output terminal T2. The other end portion of the capacitor 171 is connected to the reference potential.

### Amplifier

The amplifier 140 includes a capacitor 142, resistors 144 and 146, a transistor Tr1, input terminals T10 and T13, and output terminals T11 and T12. The input terminal T10 of the amplifier 140 is connected to an input terminal T1. One end portion of the capacitor 142 is connected to the input terminal T1. The other end portion of the capacitor 142 is connected to one end portion of the resistor 146. The other end portion of the resistor 146 is connected to a base of the transistor Tr1.

A collector of the transistor Tr1 is connected to the output terminal T11 of the amplifier 140. An emitter of the transistor Tr1 is connected to the output terminal T12 of the amplifier 140. The transistor Tr1 amplifies a signal that is inputted and outputs an amplified signal from the output terminal T11. The transistor Tr1 is, for example, a bipolar transistor. However, the present disclosure is not limited to this example. The bipolar transistor is, for example, a heterojunction bipolar transistor (HBT). However, the present disclosure is not limited to this example. The transistor Tr1 may alternatively be, for example, a field effect transistor (FET).

One end portion of the resistor 144 is connected to a connection point 141 between the capacitor 142 and the resistor 146. The other end portion of the resistor 144 is connected to the input terminal T13 of the amplifier 140. The input terminal T13 is connected to a bias circuit 150.

Here, the line 164 and the capacitor 162 form a resonant circuit 31. Further, the line 163 and the capacitor 161 form a resonant circuit 32. These two resonant circuits 31 and 32 have cutoff frequencies different from each other. In the present example, compared with the cutoff frequency of the resonant circuit 32 made up of the line 163 and the capacitor 161, the cutoff frequency of the resonant circuit 31 made up of the line 164 and the capacitor 162 is higher. Looking from the output terminal T11 of the amplifier 140, the output terminal T11 is connected to the power source 180 via the line 164 and the line 163 in this order. In other words, of these two resonant circuits described above, the resonant circuit closer to the output terminal T11 of the amplifier 140 has a higher cutoff frequency. As described above, the resonant circuit 31 having a higher cutoff frequency is arranged closer to the amplifier 140 than the resonant circuit 32 having a lower cutoff frequency. In other words, the cutoff frequency of the resonant circuit 31 arranged closer to the output terminal T11 of the amplifier 140 is made higher. By arranging the two resonant circuits 31 and 32 in the manner described above, an impedance conversion occurs in the following manner, and a more appropriate impedance matching can be provided. That is to say, at frequencies higher than the resonant frequency of the capacitor 161 and the line 163, looking from the connection point of the line 163 and the line 164 toward the line 163 side, the circuit can be viewed as the line 163 with one end portion thereof being grounded. Therefore, by the coupling between the line 163 and the line 165 and the coupling between the line 164 and the line 166, the impedance conversion is performed. At frequencies lower than the resonant frequency of the capacitor 161 and the line 163, looking from the connection point of the line 163 and the line 164 toward the line 163 side, the circuit can be viewed as the ground. Therefore, only the coupling between the line 164 and the line 166 can be seen, and compared with the case where the frequency is higher than the resonant frequency, the impedance conversion ratio becomes smaller.

Further, the two resonant circuits described above are connected in series between the output terminal T11 and the power source 180. The comparative example described above employs the configuration in which a two-stage TLT is used in between the amplifying element Q12 and the output terminal Pout. However, these TLTs are less likely to work as resonant circuits and cannot realize desired cutoffs.

### Workings

An input signal inputted to the input terminal T1 is inputted to the base of the transistor Tr1 via the resistor 146 after a direct-current component thereof is cut off by the capacitor 142. A bias is applied to the base of the transistor Tr1 from the bias circuit 150 via the resistors 144 and 146.

The emitter of the transistor Tr1 is grounded via the output terminal T12. The collector of the transistor Tr1 outputs a reversed phase signal, which is obtained by amplifying a signal applied to the base. The signal outputted from the collector of the transistor Tr1 is inputted to the matching circuit 160 via the output terminal T11. The signal inputted to the matching circuit 160 is outputted from the output terminal T2 via the lines 165 and 166 of the matching circuit 160 and the matching circuit 170.

Because of the resonance of the line 164 and the capacitor 162 and the resonance of the line 163 and the capacitor 161, unwanted signals can be cut at frequencies near the frequency of a signal to be amplified by the amplifier 140 (hereinafter, referred to as frequency f1).

### Resonant Frequency Distant From Frequency of Input Signal

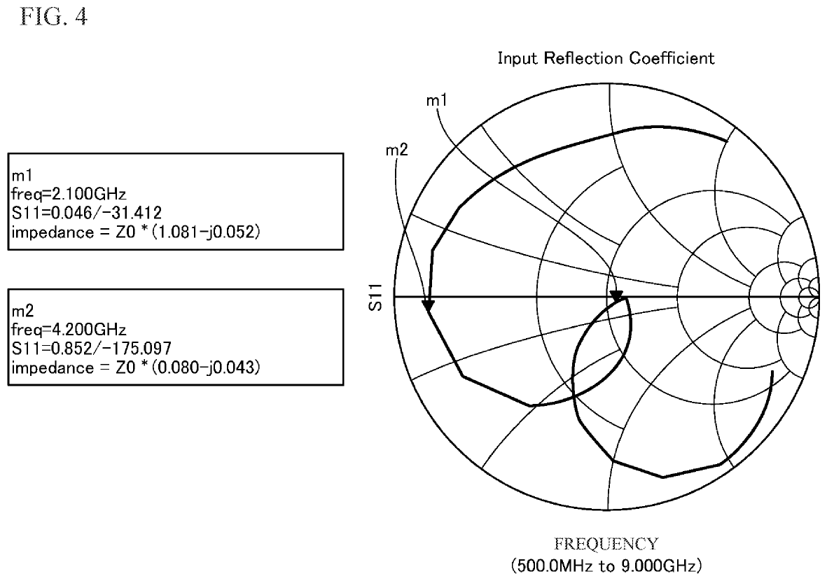

FIG. 4 to FIG. 9 are diagrams illustrating workings of the matching circuit 160 according to the first embodiment. Particularly, FIG. 4 to FIG. 9 are diagrams illustrating the workings in the case where a frequency that is away from the frequency of an input signal is a resonant frequency, that is to say, the resonant frequency is distant from the frequency of an input signal. Here, the distant frequency means, for example, a case where one frequency is twice the other frequency or higher. FIG. 4 is a Smith chart illustrating the change of an input reflection coefficient S11 with respect to the change of frequency of an input signal in the matching circuit according to the first embodiment. In the present example, the change of the input reflection coefficient S11 is illustrated when the frequency of an input signal is varied from 500.0 MHz to 9.000 GHz.

The position of a marker m1 in FIG. 4 is 2.100 GHz in frequency (freq), the input reflection coefficient S11=0.0046/−31.412, and the characteristic impedance=Z0*(1.081−j0.052). The position of a marker m2 is 4.200 GHz in frequency, the input reflection coefficient S11=0.852/−175.097, and the characteristic impedance=Z0* (0.0080−j0.043). The position of the marker m2 is Z0=0, that is, a short-circuited position or a position close to the short-circuited position. In other words, at the frequency twice the frequency=2.100 GHz (that is, second order harmonics), the characteristic impedance can be set to substantially 0. By setting the impedance of second order harmonics to be short-circuited (short) and setting the impedance of third order harmonics to be, for example, within a region between 70 degrees to 140 degrees on the Smith chart, the amplifier 140, by which these loads are being seen, operates as a Class F amplifier. This enables the realization of high efficiency. Further, by setting the impedance of third order harmonics to be short-circuited (short) and setting the impedance of second order harmonics to be, for example, within a region between 70 degrees to 140 degrees on the Smith chart, the amplifier 140, by which these loads are being seen, operates as an inverse Class F amplifier. This enables the realization of high efficiency.

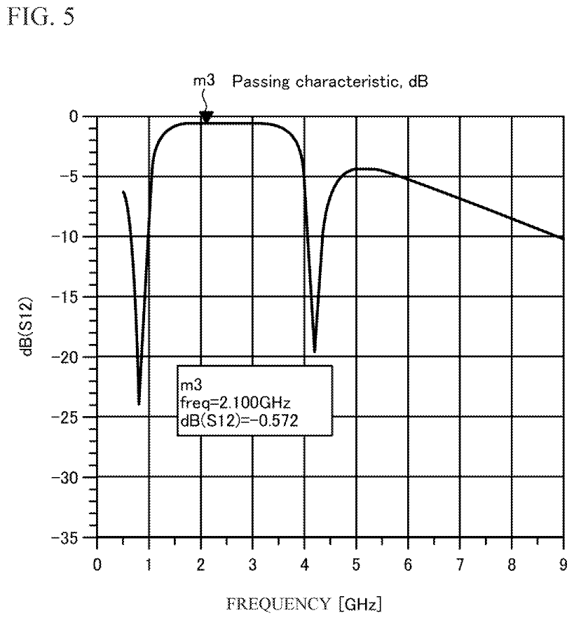

FIG. 5 is a diagram illustrating the change of the output transmission coefficient (passing characteristic) S12 with respect to the frequency of an input signal. In FIG. 5, the horizontal axis represents the frequency GHz of an input signal, and the vertical axis represents the signal intensity dB. The position of a marker m3 in FIG. 5 indicates that the signal intensity is −0.572 dB at the frequency=2.100 GHz. Referring to FIG. 5, the resonance of the line 163 and the capacitor 161 is realized at the frequency=0.8 GHz, and the value of the output transmission coefficient S12 decreases. Further, a resonance of the line 164 and the capacitor 162 is realized at the frequency=4.3 GHz, and the value of the output transmission coefficient S12 decreases.

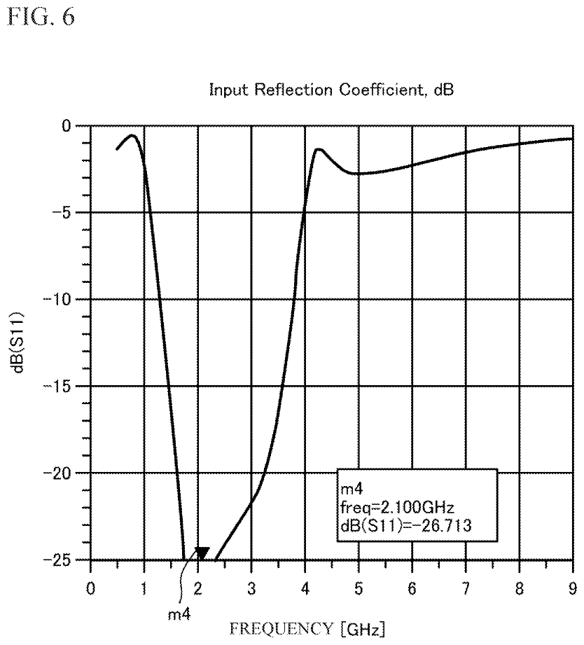

FIG. 6 is a diagram illustrating the change of the input reflection coefficient S11 with respect to the frequency of an input signal. In FIG. 6, the horizontal axis represents the frequency GHz of an input signal, and the vertical axis represents the signal intensity dB. The position of a marker m4 in FIG. 6 indicates that the signal intensity is −26.713 dB at the frequency=2.100 GHz.

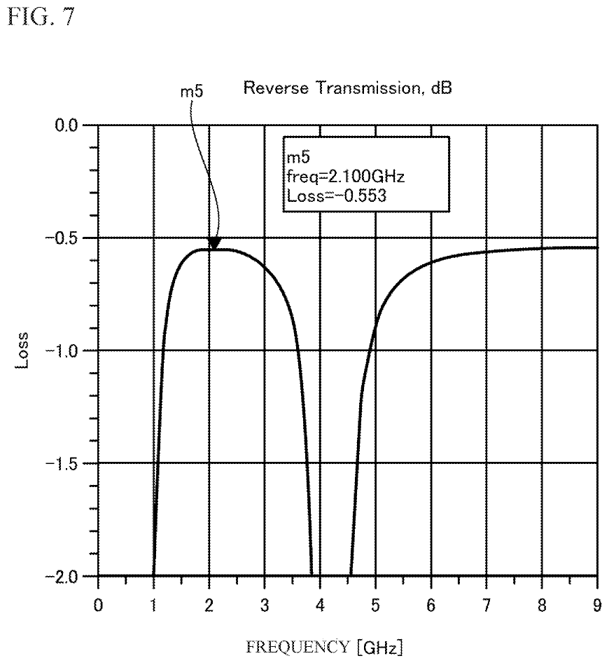

FIG. 7 is a diagram illustrating the passing loss with respect to the change of frequency. In FIG. 7, the horizontal axis represents the frequency GHz of an input signal, and the vertical axis represents the passing loss (Loss) dB. At the position of a marker m5 in FIG. 7, the frequency=2.100 GHz and the loss is −0.553 dB. It illustrates that at the frequency=2.100 GHz, the loss is low, that is, the signal intensity is high. As illustrated in FIG. 4 to FIG. 7, the matching circuit 160 according to the first embodiment can realize resonant states at a frequency band of a signal that needs to be amplified and frequencies that need to be cut.

### Resonant Frequency Near Frequency of Input Signal

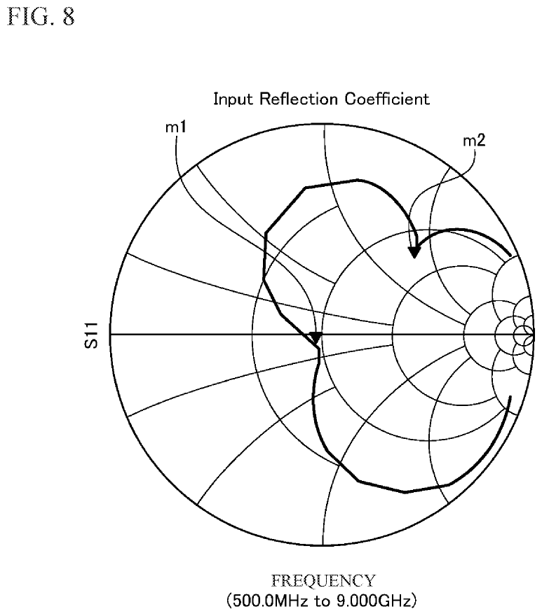

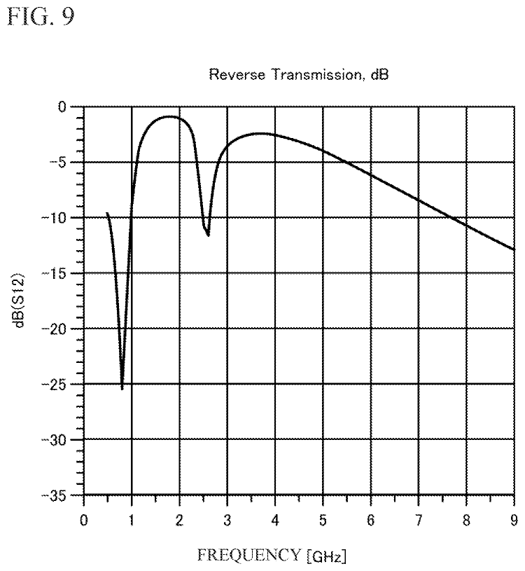

FIG. 8 and FIG. 9 are diagrams illustrating the workings in the case where a frequency that is not far from the frequency of an input signal is the resonant frequency, that is to say, the resonant frequency is near the frequency of an input signal. Here, the near frequency means, for example, a case where one frequency is less than twice the other frequency.

FIG. 8 is a Smith chart illustrating the change of the input reflection coefficient S11 with respect to the change of the frequency of an input signal. FIG. 9 is a diagram illustrating the change of the output transmission coefficient S12 with respect to the change of the frequency of an input signal. In FIG. 9, the horizontal axis represents the frequency GHz of an input signal, and the vertical axis represents the signal intensity dB.

As illustrated in FIG. 8 and FIG. 9, by realizing the resonant state by the line 163 and the capacitor 161 and the resonant state by the line 164 and the capacitor 162 at frequencies not far from the frequency f1, unwanted signals can be cut at frequencies near the frequency f1. Referring to FIG. 9, there are poles caused by the respective resonances at a frequency of 0.9 GHz and a frequency of 2.4 GHz. These poles correspond to markers m1 and m2 of FIG. 8. The resonant frequency caused by the resonant circuit 31 is equal to or higher than 1.25 times the frequency of the signal to be amplified by the amplifier 140 and less than twice the frequency of the signal to be amplified by the amplifier 140. The resonant frequency caused by the resonant circuit 32 is equal to or higher than 0.45 times the frequency of the signal to be amplified by the amplifier 140 and equal to or less than 0.85 times the frequency of the signal to be amplified by the amplifier 140. Further, referring to FIG. 8, it is clear that the impedance seen from the amplifier 140 at the frequency f1 can be set at a desired value.

Here, the pole at a frequency of 2.4 GHz realizes attenuation at frequencies from 2.4 GHz to 2.48 GHz, which is the ISM (Industrial Scientific and Medical Band) band.

The pole at a frequency of 0.9 GHz realizes attenuation of a mixing signal 2×f1−f_ISM (0.94 GHz) of 2×f1 (for example, 2×1.71GHz) and an ISM band signal f_ISM.

### Effects

As described above, the matching circuit 160 according to the first embodiment can provide a sufficient cutoff characteristic even in the case where a frequency band of a signal that needs to be amplified and frequencies that need to be cut are not sufficiently separated. This is because a filter characteristic with high Q factor can be realized by a plurality of resonant circuits. That is to say, filter performance with high Q factor can be provided by arranging the resonant circuits 31 and 32 in series between the amplifier 140 and the power source 180 and further by electromagnetically coupling the line 164 included in the resonant circuit 31 and the line 163 included in the resonant circuit 32 with the line 165 and the line 166, through which a radio frequency signal outputted from the amplifier 140 is transmitted, respectively.

### Second Embodiment

### Configuration

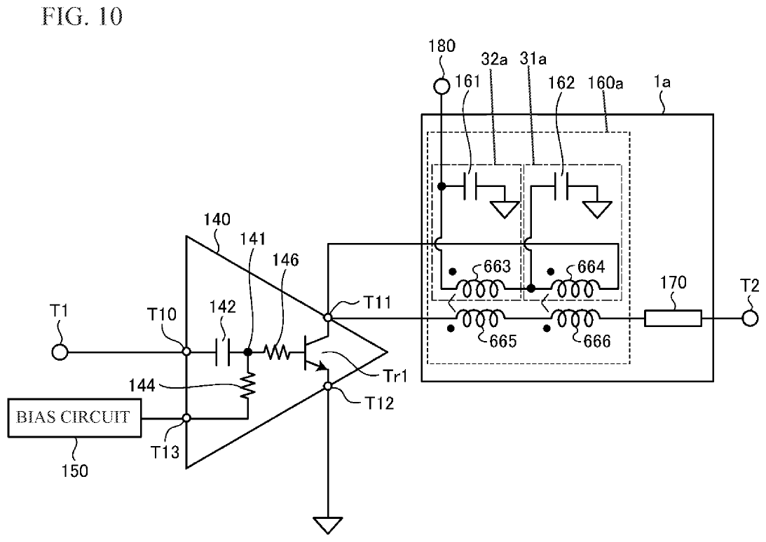

FIG. 10 is a diagram illustrating a configuration of a matching circuit according to the second embodiment of the present disclosure. In FIG. 10, instead of the lines of the first embodiment, a matching circuit 160a according to the second embodiment of the present disclosure uses inductors. That is to say, the matching circuit 160a has a configuration in which the lines 163, 164, 165, and 166 of the first embodiment are replaced with inductors 663, 664, 665, and 666.

A resonant circuit 31a includes the inductor 664 and the capacitor 162. A resonant circuit 32a includes the inductor 663 and the capacitor 161. The inductors 663, 664, 665, and 666 are all inductance elements. The inductor 664 that is the first inductance element and the inductor 666 that is the fourth inductance element are electromagnetically coupled with each other. The inductor 663 that is the second inductance element and the inductor 665 that is the third inductance element are electromagnetically coupled with each other. The electromagnetic coupling with each other corresponds to coupling of coils each having the same number of turns.

### Workings

As is the case with the matching circuit 160 according to the first embodiment, the matching circuit 160a according to the second embodiment can realize the resonant states at a frequency band of a signal that needs to be amplified and frequencies that need to be cut.

### Effects

As is the case with the matching circuit 160 according to the first embodiment, the matching circuit 160a according to the second embodiment can provide a sufficient cutoff characteristic even in the case where a frequency band of a signal that needs to be amplified and frequencies that need to be cut are not sufficiently separated.

### Third Embodiment

### Configuration

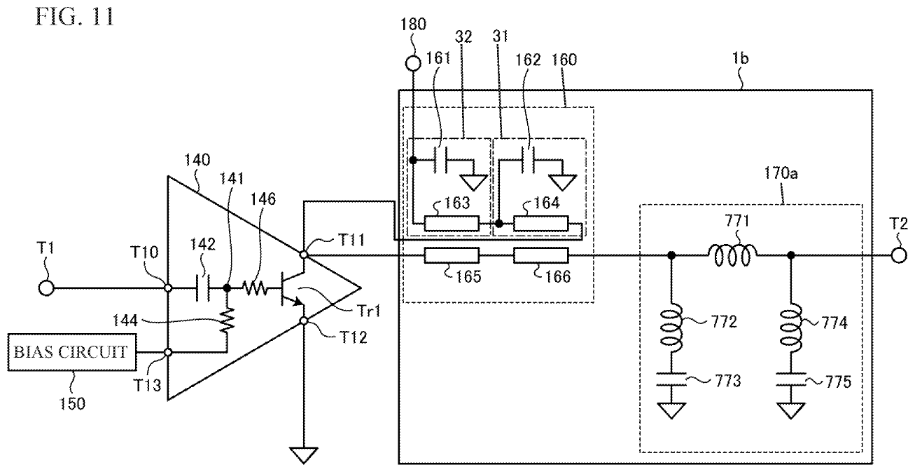

FIG. 11 is a diagram illustrating a configuration of a matching circuit according to the third embodiment of the present disclosure. In FIG. 11, a matching circuit 1b according to the third embodiment of the present disclosure has a configuration in which a matching circuit 170a that is the second matching circuit is provided on the output side of the matching circuit 160. That is to say, in the third embodiment, the matching circuit 170a is included between the matching circuit 160 of the first embodiment and the output terminal T2.

The matching circuit 170a includes an inductor 771 that is a first inductor, an inductor 772 that is a second inductor, an inductor 774 that is a third inductor, a capacitor 773 that is a third capacitor, and a capacitor 775 that is a fourth capacitor. One end portion of the inductor 771 is connected to the line 166. One end portion of the inductor 772 is connected to the one end portion of the inductor 771. The other end portion of the inductor 772 is connected to one end portion of the capacitor 773. The other end portion of the capacitor 773 is connected to the reference potential. One end portion of the inductor 774 is connected to the other end portion of the inductor 771. The other end portion of the inductor 774 is connected to one end portion of the capacitor 775. The other end portion of the capacitor 775 is connected to the reference potential. In other words, the matching circuit 170a is a π-type circuit of a series resonant circuit made up of the inductor 772 and the capacitor 773, the inductor 771, and a series resonant circuit made up of the inductor 774 and the capacitor 775. A resonant frequency of the series resonant circuit made up of the inductor 772 and the capacitor 773 is a double frequency of the frequency f1. Further, a resonant frequency of the series resonant circuit made up of the inductor 774 and the capacitor 775 is a triple frequency of the frequency f1. Note that instead of the inductor 771, a parallel resonant circuit of an inductor and a capacitor may be employed.

### Workings

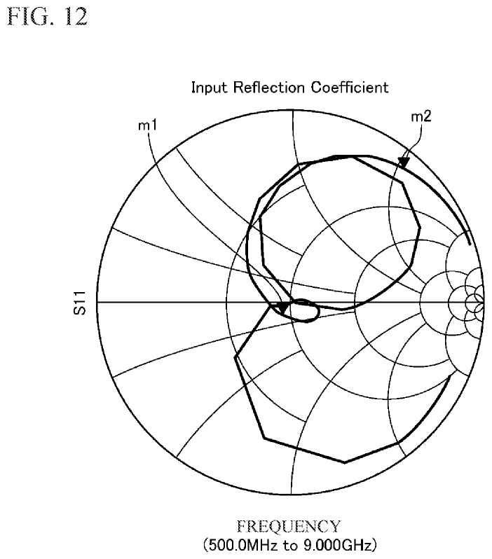

FIG. 12 is a Smith chart illustrating the change of the input reflection coefficient S11 with respect to the change of the frequency of an input signal in the matching circuit according to the third embodiment. The Smith chart of FIG. 12 illustrates the load impedance seen from the amplifier 140 toward the output terminal T2 side. In the present example, the change of the input reflection coefficient S11 is illustrated when the frequency of an input signal is varied from 500.0 MHz to 9.000 GHz.

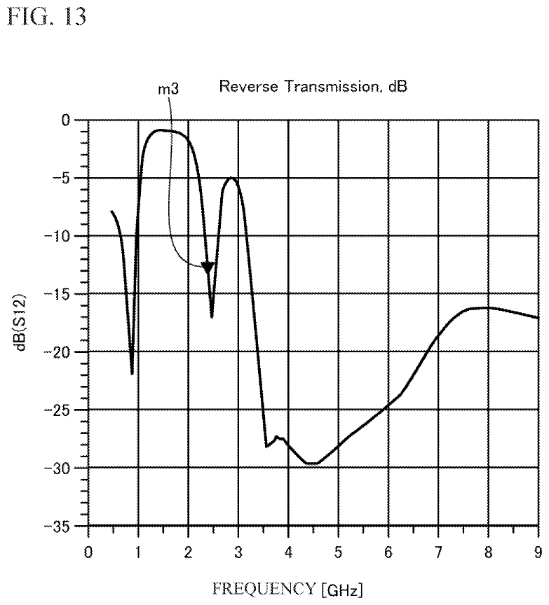

FIG. 13 is a diagram illustrating the change of the output transmission coefficient S12 with respect to the frequency of an input signal. In FIG. 13, the horizontal axis represents the frequency GHz of an input signal, and the vertical axis represents the signal intensity dB.

As illustrated in FIG. 12 and FIG. 13, in addition to characteristic features illustrated in FIG. 8 and FIG. 9, the matching circuit 1b according to the third embodiment of the present disclosure can realize attenuation at the double frequency and the triple frequency of the frequency f1. However, the “double frequency” or the “triple frequency” described in the present disclosure is not the value of the resonant frequency but a frequency at which attenuation can be realized. The resonant frequency can be deviated slightly from the doubled value or the tripled value so long as the attenuation is realized at the “double frequency” or the “triple frequency”. A marker m1 in FIG. 12 is the impedance at the frequency f1, and a desired impedance can be realized. As illustrated in FIG. 13, resonant states are achieved at a frequency of 0.9 GHz and a frequency of 2.4 GHz.

### Effects

As is the case with the matching circuit 160 according to the first embodiment, the matching circuit 1b according to the third embodiment can provide a sufficient cutoff characteristic even in the case where a frequency band of a signal that needs to be amplified and a plurality of frequencies that needs to be cut are not sufficiently separated.

### Fourth Embodiment

### Configuration

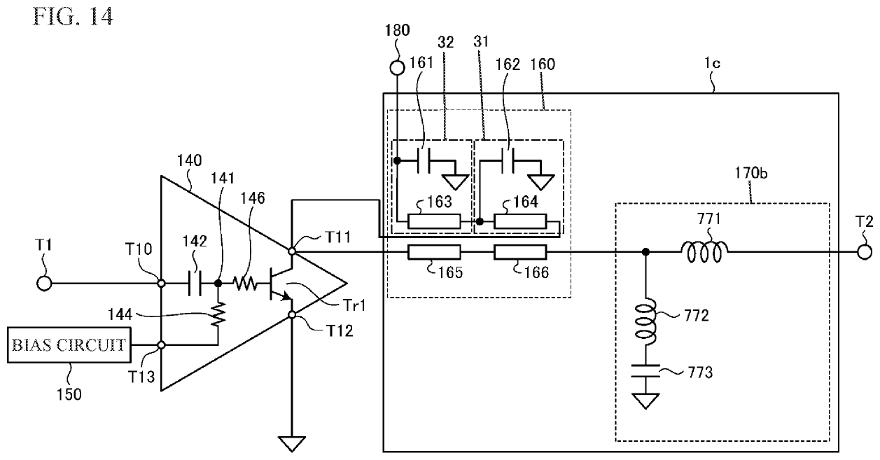

FIG. 14 is a diagram illustrating a configuration of a matching circuit according to the fourth embodiment of the present disclosure. In FIG. 14, instead of the matching circuit 170a of FIG. 11, a matching circuit 1c according to the fourth embodiment of the present disclosure employs a matching circuit 170b that is the second matching circuit. Of the matching circuit 170a of FIG. 11, the matching circuit 170b includes the inductor 771, the inductor 772, and the capacitor 773. One end portion of the inductor 771 that is the first inductor is connected to the line 166 that is the fourth inductance element. One end portion of the inductor 772 that is the second inductor is connected to the one end portion of the inductor 771. The other end portion of the inductor 772 is connected to one end portion of the capacitor 773 that is the third capacitor. The other end portion of the capacitor 773 is connected to the reference potential. Note that instead of the inductor 771, a parallel resonant circuit of an inductor and a capacitor may be employed.

### Workings

Of the matching circuit 170a of FIG. 11, the matching circuit 170b includes the inductor 771, the inductor 772, and the capacitor 773. Because of this, for example, the resonant state is achieved at the frequency twice the frequency f1.

### Effects

The matching circuit 1c according to the fourth embodiment can provide a sufficient cutoff characteristic even in the case where a frequency band of a signal that needs to be amplified and frequencies that need to be cut are not sufficiently separated.

### Fifth Embodiment

### Configuration

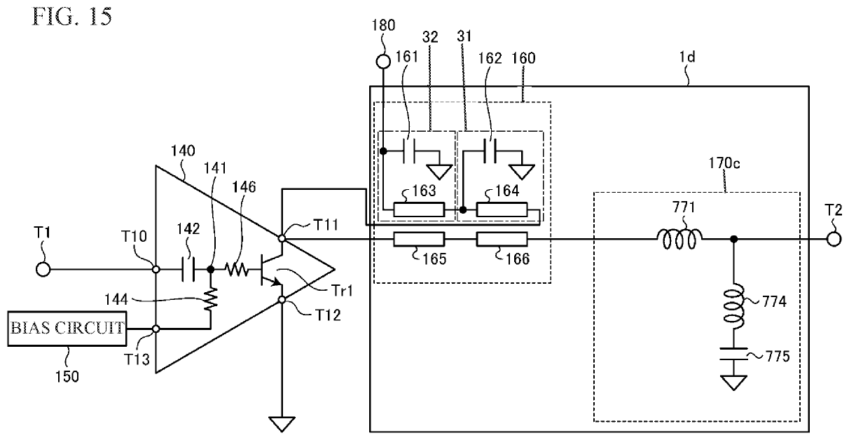

FIG. 15 is a diagram illustrating a configuration of a matching circuit according to the fifth embodiment of the present disclosure. In FIG. 15, instead of the matching circuit 170a of FIG. 11, a matching circuit 1d according to the fifth embodiment of the present disclosure employs a matching circuit 170c. Of the matching circuit 170a of FIG. 11, the matching circuit 170c that is the second matching circuit includes the inductor 771, the inductor 774, and the capacitor 775 that is the fourth capacitor. One end portion of the inductor 771 that is the first inductor is connected to the line 166. One end portion of the inductor 774 that is the third inductor is connected to the other end portion of the inductor 771. The other end portion of the inductor 774 is connected to one end portion of the capacitor 775. The other end portion of the capacitor 775 is connected to the reference potential. Note that instead of the inductor 771, a parallel resonant circuit of an inductor and a capacitor may be employed.

### Workings

Of the matching circuit 170a of FIG. 11, the matching circuit 170c includes the inductor 771, the inductor 774, and the capacitor 775. Because of this, for example, the resonant state is realized at the frequency three times the frequency f1.

### Effects

The matching circuit 1d according to the fifth embodiment can provide a sufficient cutoff characteristic even in the case where a frequency band of a signal that needs to be amplified and frequencies that need to be cut are not sufficiently separated.

### Sixth Embodiment

### Configuration

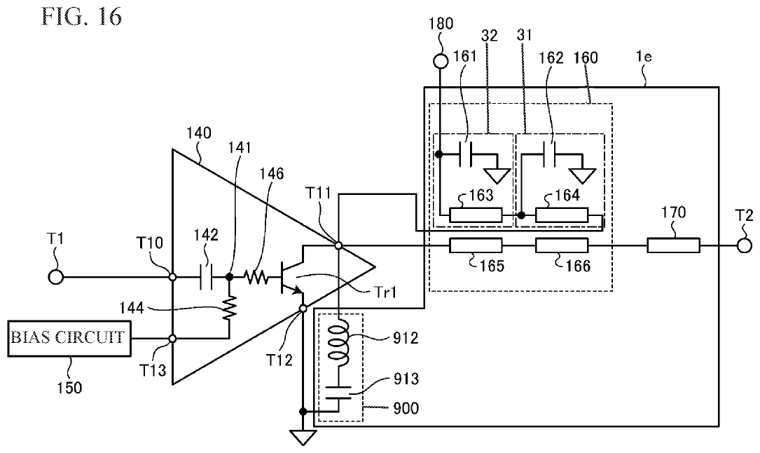

FIG. 16 is a diagram illustrating a configuration of a matching circuit according to a sixth embodiment of the present disclosure. As illustrated in FIG. 16, a matching circuit 1e according to the sixth embodiment includes a matching circuit 900 that is a third matching circuit in addition to the matching circuits 160 and 170.

The matching circuit 900 includes an inductor 912 that is a fourth inductor and a capacitor 913 that is a fifth capacitor. One end portion of the inductor 912 is connected to the output terminal T11 of the amplifier 140. The other end portion of the inductor 912 is connected to one end portion of the capacitor 913. The other end portion of the capacitor 913 is connected to the reference potential.

Further, the one end portion of the inductor 912 is connected to the collector terminal of the transistor Tr1 via the output terminal T11. The other end portion of the capacitor 913 is connected to the emitter terminal of the transistor Tr1 via the output terminal T12. Note that in the case where the transistor Tr1 is an field effect transistor, the other end portion of the capacitor 913 is connected to the source terminal and the one end of the inductor 912 is connected to the drain terminal.

### Workings

In the matching circuit 1e according to the sixth embodiment, the matching circuit 900 sets the impedance to be short-circuited or close thereto at the double frequency or the triple frequency of the frequency of a signal to be amplified by the amplifier 140.

### Effects

The matching circuit 1e according to the sixth embodiment can set the cutoff frequency at a desired frequency and can provide a sufficient cutoff characteristic even in the case where a frequency band of a signal that needs to be amplified and frequencies that need to be cut are not sufficiently separated.

With regard to the description of the claims, the present disclosure can take the following aspects.

<1> A matching circuit that is provided on an output side of an amplifier and provides impedance matching, the matching circuit comprising: a first matching circuit, wherein the first matching circuit includes a first resonant circuit connected to an output terminal of the amplifier and a second resonant circuit connected between the first resonant circuit and a power source, the first resonant circuit includes a first inductance element and a first capacitor, the second resonant circuit includes a second inductance element and a second capacitor, one end portion of the first inductance element is connected to the output terminal of the amplifier, another end portion of the first inductance element is connected to one end portion of the second inductance element and one end portion of the first capacitor, another end portion of the second inductance element is connected to the power source and one end portion of the second capacitor, another end portion of the first capacitor is connected to a reference potential, another end portion of the second capacitor is connected to the reference potential, the first matching circuit further includes a third inductance element connected to the output terminal of the amplifier and a fourth inductance element connected to an output side of the third inductance element, the second inductance element and the third inductance element are electromagnetically coupled with one another, and the first inductance element and the fourth inductance element are electromagnetically coupled with one another.

<2> The matching circuit according to <1>, wherein a resonant frequency of the first resonant circuit is equal to or higher than 1.25 times a frequency of a signal to be amplified by the amplifier and equal to or less than 2.5 times the frequency of a signal to be amplified by the amplifier, and a resonant frequency of the second resonant circuit is equal to or higher than 0.45 times the frequency of a signal to be amplified by the amplifier and equal to or less than 0.85 times the frequency of a signal to be amplified by the amplifier.

<3> The matching circuit according to <1>or <2>, further comprising: a second matching circuit provided on an output side of the first matching circuit.

<4> The matching circuit according to <3>, wherein the second matching circuit includes a first inductor, a second inductor, a third inductor, a third capacitor, and a fourth capacitor, one end portion of the first inductor is connected to the fourth inductance element, one end portion of the second inductor is connected to the one end portion of the first inductor, another end portion of the second inductor is connected to one end portion of the third capacitor, another end portion of the third capacitor is connected to the reference potential, one end portion of the third inductor is connected to another end portion of the first inductor, another end portion of the third inductor is connected to one end portion of the fourth capacitor, and another end portion of the fourth capacitor is connected to the reference potential.

<5> The matching circuit according to <3>, wherein the second matching circuit includes a first inductor, a second inductor, and a third capacitor, one end portion of the first inductor is connected to the fourth inductance element, one end portion of the second inductor is connected to the one end portion of the first inductor, another end portion of the second inductor is connected to one end portion of the third capacitor, and another end portion of the third capacitor is connected to the reference potential.

<6> The matching circuit according to <3>, wherein the second matching circuit includes a first inductor, a third inductor, and a fourth capacitor, one end portion of the first inductor is connected to the fourth inductance element, one end portion of the third inductor is connected to another end portion of the first inductor, another end portion of the third inductor is connected to one end portion of the fourth capacitor, and another end portion of the fourth capacitor is connected to the reference potential.

<7> The matching circuit according to any one of <3>to <6>, wherein the second matching circuit attenuates a signal at least one of a frequency twice a frequency of a signal to be amplified by the amplifier and a frequency three times the frequency of a signal to be amplified by the amplifier.

<8> The matching circuit according to any one of <1>to <7>, further comprising: a third matching circuit connected to the output terminal of the amplifier, wherein the third matching circuit includes a fourth inductor and a fifth capacitor, one end portion of the fourth inductor is connected to the output terminal of the amplifier, another end portion of the fourth inductor is connected to one end portion of the fifth capacitor, and another end portion of the fifth capacitor is connected to the reference potential.

<9>The matching circuit according to <8>, wherein an impedance is set to be short-circuited or close thereto at a frequency twice a frequency of a signal to be amplified by the amplifier or a frequency three times the frequency of a signal to be amplified by the amplifier.

<10>The matching circuit according to <8>, wherein the amplifier includes a transistor for amplifying a signal, and the another end portion of the fifth capacitor is connected to an emitter terminal or a source terminal of the transistor.

<11>The matching circuit according to any one of <1>to <9>, wherein the amplifier is an amplifier that carries out a class F operation.

What is claimed is:

1. A matching circuit that is on an output side of an amplifier and that is configured to provide impedance matching, the matching circuit comprising:
a first matching circuit comprising:
a first resonant circuit connected to an output terminal of the amplifier,
a second resonant circuit connected between the first resonant circuit and a power source,
a third inductance element, and
a fourth inductance element,
wherein the first resonant circuit comprises a first inductance element and a first capacitor,
wherein the second resonant circuit comprises a second inductance element and a second capacitor,
wherein a first end of the first inductance element is connected to the output terminal of the amplifier,
wherein a second end of the first inductance element is connected to a first end of the second inductance element and to a first end of the first capacitor,
wherein a second end of the second inductance element is connected to the power source and to a first end of the second capacitor,
wherein a second end of the first capacitor is connected to a reference potential,
wherein a second end of the second capacitor is connected to the reference potential,
wherein the third inductance element is connected to the output terminal of the amplifier and the fourth inductance element is connected to an output of the third inductance element,
wherein the second inductance element and the third inductance element are electromagnetically coupled with one another, and
wherein the first inductance element and the fourth inductance element are electromagnetically coupled with one another.

2. The matching circuit according to claim 1,
wherein a resonant frequency of the first resonant circuit is equal to or greater than 1.25 times a frequency of a signal amplified by the amplifier, and is equal to or less than 2.5 times the frequency of the signal amplified by the amplifier, and
wherein a resonant frequency of the second resonant circuit is equal to or greater than 0.45 times the frequency of the signal amplified by the amplifier, and is equal to or less than 0.85 times the frequency of the signal amplified by the amplifier.

3. The matching circuit according to claim 1, further comprising:
a second matching circuit on an output side of the first matching circuit.

4. The matching circuit according to claim 2, further comprising:
a second matching circuit on an output side of the first matching circuit.

5. The matching circuit according to claim 3,
wherein the second matching circuit comprises a first inductor, a second inductor, a third inductor, a third capacitor, and a fourth capacitor,
wherein a first end of the first inductor is connected to the fourth inductance element,
wherein a first end of the second inductor is connected to the one end portion of the first inductor,
wherein a second end of the second inductor is connected to a first end portion of the third capacitor,
wherein a second end of the third capacitor is connected to the reference potential,
wherein a first end of the third inductor is connected to a second end of the first inductor,
wherein a second end of the third inductor is connected to a first end of the fourth capacitor, and
wherein a second end of the fourth capacitor is connected to the reference potential.

6. The matching circuit according to claim 3,
wherein the second matching circuit comprises a first inductor, a second inductor, and a third capacitor,
wherein a first end of the first inductor is connected to the fourth inductance element,
wherein a first end of the second inductor is connected to the first end of the first inductor,
wherein a second end of the second inductor is connected to a first end of the third capacitor, and
wherein a second end of the third capacitor is connected to the reference potential.

7. The matching circuit according to claim 3,
wherein the second matching circuit comprises a first inductor, a third inductor, and a fourth capacitor,
wherein a first end of the first inductor is connected to the fourth inductance element,
wherein a first end of the third inductor is connected to a second end of the first inductor,
wherein a second end of the third inductor is connected to a first end of the fourth capacitor, and
wherein a second end of the fourth capacitor is connected to the reference potential.

8. The matching circuit according to claim 3, wherein the second matching circuit is configured to attenuate signals having a frequency that is twice a frequency of a signal amplified by the amplifier, or signals having a frequency three times the frequency of the signal amplified by the amplifier.

9. The matching circuit according to claim 1, further comprising:
a third matching circuit connected to the output terminal of the amplifier,
wherein the third matching circuit comprises a fourth inductor and a fifth capacitor,
wherein a first end of the fourth inductor is connected to the output terminal of the amplifier,
wherein a second end of the fourth inductor is connected to a first end portion of the fifth capacitor, and
wherein a second end of the fifth capacitor is connected to the reference potential.

10. The matching circuit according to claim 9, wherein an impedance of the matching circuit is a short-circuit impedance at a frequency twice a frequency of a signal amplified by the amplifier or at a frequency three times the frequency of the signal amplified by the amplifier.

11. The matching circuit according to claim 9,
wherein the amplifier comprises a transistor configured to amplify the signal, and
wherein the second end of the fifth capacitor is connected to an emitter terminal or a source terminal of the transistor.

12. The matching circuit according to claim 1, wherein the amplifier is a class F amplifier.

13. The matching circuit according to claim 2, wherein the amplifier is a class F amplifier.
